(19) United States
(12) Patent Application Publication
(10) Pub. No.: US 2012/0049216 A1
(43) Pub. Date: Mar. 1, 2012

(54) ALTERNATING CURRENT LIGHT-EMITTING DEVICE

(75) Inventors: YI-SHENG TING, TAOYUAN (TW); WEI-KANG CHENG, TAOYUAN (TW); SHYI-MING PAN, TAOYUAN (TW)

(73) Assignee: FORMOSA EPITAXY INCORPORATION, TAOYUAN COUNTY (TW)

(21) Appl. No.: 12/898,945

(22) Filed: Oct. 6, 2010

(30) Foreign Application Priority Data
Aug. 24, 2010 (TW) 099128163

(51) Int. Cl. H01L 33/50

(52) U.S. Cl. 257/98; 257/E33.068

(57) ABSTRACT

The present invention provides an alternating current light-emitting diode (AC LED), which uses a light compensation layer disposed on the light-emitting surface of the AC LED. The materials of the light compensation layer can be phosphorescent or fluorescent materials. The light-emitting mechanism is mainly the light-emitting mechanism of electron-hole pairs in a triplet state. By absorbing light of the AC LED, the flashes occurred when the power of the AC LED alters from a positive half-cycle to a negative one can be compensated. Thereby, the AC LED can emit light full-timely.

### FIELD OF THE INVENTION

The present invention relates generally to a light-emitting diode (LED), and particularly to an alternating current (AC) LED.

### BACKGROUND OF THE INVENTION

Although traditional incandescent lamps are cheap, they suffer the drawbacks of low efficiency, high power consumption, and short lifetime. As for fluorescent lamps, they bring about pollution problems owing to mercury contained in their waste.

LEDs own the properties of endurable light emitting, long lifetime, lightness, and low power consumption. Besides, they also have other advantages, such as cold operation capability, broad operating temperature ranges, at least 100 thousand hours of lifetime, and even containing no hazard materials such as mercury. Thereby, LEDs indeed are ideal next-generation light sources.

In general, LEDs are extensively applied to white-light illuminating apparatuses, indicators, automobile signal lights, automobile headlamps, flashlights, backlight modules of LCD, light sources of projectors, outdoor displaying units, and so forth. However, transformers and rectifiers are required for these applications. These extra circuitries increase manufacturing costs of lamps, occupy additional space and thus affecting their looks, and produce additional heat, which deteriorate long-term safety of lamps, let alone the lifetime limitations of the extra circuitries shorten the lifetime of lamps, making LEDs' long-lifetime advantage in vain.

According to the stable development of optoelectronic technology, companies in the world all invest a great deal of resources to the development of relevant technologies. In Jan. 26, 2005, product announcement by Seoul Semiconductor Co., Ltd of Korea and III-N Technology of US reveal that commercialization of AC LEDs must be developed in a global scale. In the development of AC light-emitting microchip technology, there exists a bridge AC LED structure that solved the problem, occurred in the early time of AC LED development, of unable to emit light in both positive and negative alternating cycles (full-time light emitting). It adopted the design concept of Wheatstone bridge to improve the problem that only a half during the cycle can contribute to light emitting. However, because the rectifying devices of the bridge AC LED structure use AC light-emitting microchips directly, it will result in two drawbacks. First, because the endurance of reverse biases for a single rectifying device (a single AC light-emitting microchip) is inferior, the amount of adopted rectifying devices cannot be reduced. In other words, multiple AC light-emitting microchips have to be connected in series with the Wheatstone bridge for sharing the reverse bias applied by AC power. Taking the 110V grid for example, the peak voltage of the reverse bias applied by AC power us approximately 156V (110×√2). Thereby, 20 AC light-emitting microchips on the path of the positive and negative half-waves of AC signals are needed for sharing the reverse bias and avoiding reverse-bias breakdown. Consequently, the total amount of required rectifying devices is approximately 20×2=40 (AC light-emitting microchips on the path of the positive and negative half-waves of AC signals). Meanwhile, the number of the AC light-emitting microchips used for emitting light is reduced to 110V/3.1V (the enabling voltage of each AC light-emitting microchip)−20 (the number of AC light-emitting microchips used for rectifying)=15. It is known that the number of AC light-emitting microchips used for rectifying is much greater than that for emitting light. In addition, because the amounts of power consumption for both type of light-emitting devices (AC light-emitting microchips) are identical, the proportion of input power wasted on rectifying devices will remain high, resulting in inferior overall efficiency. Secondly, although the light-emitting area, compared to the design of earlier AC LEDs, has increased, there are still numerous rectifying devices wasting the overall light-emitting area owing to incapability of emitting light during reverse biases. Accordingly, the problem of full-time light emitting for an AC LED has become the most crucial issue in the field.

### SUMMARY

An objective of the present invention is to provide an AC LED, which uses a light compensation layer disposed on the light-emitting surface of the AC LED. Thereby, the AC LED is able to emit light full-timely.

In order to achieve the objective described above, the present invention provides an AC LED, which uses a light compensation layer disposed on the light-emitting surface of the AC LED. The materials of the light compensation layer can be phosphorescent or fluorescent materials. The light-emitting mechanism is mainly the light-emitting mechanism of electron-hole pairs in a triplet state. By absorbing light of the AC LED, the flashes occurred when the power of the AC LED alters from a positive half-cycle to a negative one can be compensated. Thereby, the AC LED can emit light full-timely.

### BRIEF DESCRIPTION OF THE DRAWINGS

FIG. 1 shows a structural schematic diagram according to a preferred embodiment of the present invention;

FIG. 2A shows cycles of power according to a preferred embodiment of the present invention;

FIG. 2B shows the relation between cycles of power and light intensity according to a preferred embodiment of the present invention;

FIG. 2C shows a schematic diagram of reduced flashes according to a preferred embodiment of the present invention;

FIG. 3 shows a structural schematic diagram according to another preferred embodiment of the present invention;

FIG. 4 shows a structural schematic diagram according to another preferred embodiment of the present invention;

FIG. 5 shows a structural schematic diagram according to another preferred embodiment of the present invention; and

FIG. 6 shows a structural schematic diagram according to another preferred embodiment of the present invention.

### DETAILED DESCRIPTION

In order to make the structure and characteristics as well as the effectiveness of the present invention to be further understood and recognized, the detailed description of the present invention is provided as follows along with embodiments and accompanying figures.

The present invention solves the problem of flashes occurred in the prior art when the power of an AC LED alters from a positive half-cycle to a negative one. The present invention provides a light compensation layer to make an AC LED emit light full-timely.

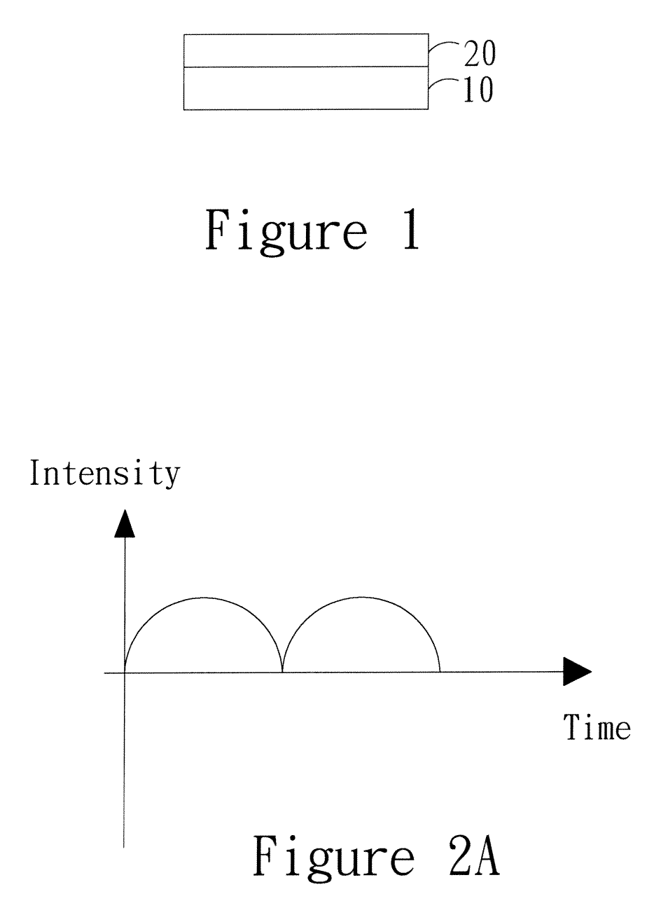

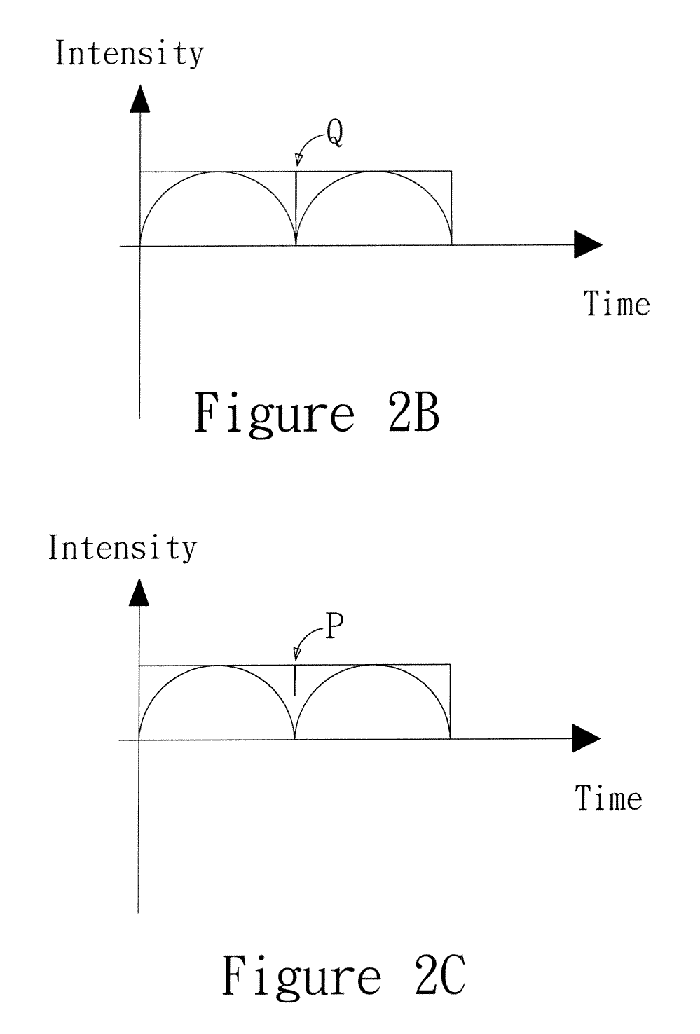

FIGS. 1, 2A, 2B, and 2C show a structural schematic diagram, cycles of power, the relation between cycles of power and light intensity, and a schematic diagram of reduced flashes, respectively, according to a preferred embodiment of the present invention. As shown in the figures, the present invention provides an AC LED structure, which comprises an AC LED 10 and a light compensation layer 20, which is disposed on the light-emitting surface of the AC LED 10.

When the power alters from a positive half-cycle to a negative one (as shown in FIG. 2A), the AC LED flashes at the point Q as shown in FIG. 2B. The present uses the light compensation layer to absorb light from the AC LED, and emit light when a positive half-cycle alters to a negative one and thus compensating the light intensity at flashes as shown at the point P of FIG. 2C. Accordingly, the AC LED can emit light full-timely, eliminating the drawback of flashes caused by the property of AC power.

Besides, the AC LED can be a red, blue, green, white, ultraviolet, or any combination of the above AC LED. The light compensation layer 20 is not the fluorescent or phosphorescent layer of a white (blue LED adopts Yag or Tag) or other-color LED used for converting light of the LED into a specific light. The light compensation layer 20 according to the present invention is used as a compensation mechanism for compensating the specific light when the LED flashes.

The material of the light compensation layer 20 is chosen from the group consisting of yellow phosphorescent powders, red phosphorescent powders, and any combination of the above, for example, ZnS, CaS, SrAl₂O₄, CaAl₂O₄, CaSrS, Sr₄Al₁₄O₂₅, and coordination compounds containing Pd.

For instance, if blue LED chip is used, it is required to use yellow fluorescent powders for light conversion to mix the blue LED and produce white light. On the other hand, the light compensation layer 20 according to the present invention can be chosen from the group consisting of yellow phosphorescent powders, green phosphorescent powders, red phosphorescent powders, yellow fluorescent powders, green fluorescent powders, red fluorescent powders, and any combination of the above. According to design purpose, the light compensation layer 20 can emit any color of light at the transient moments of flashes.

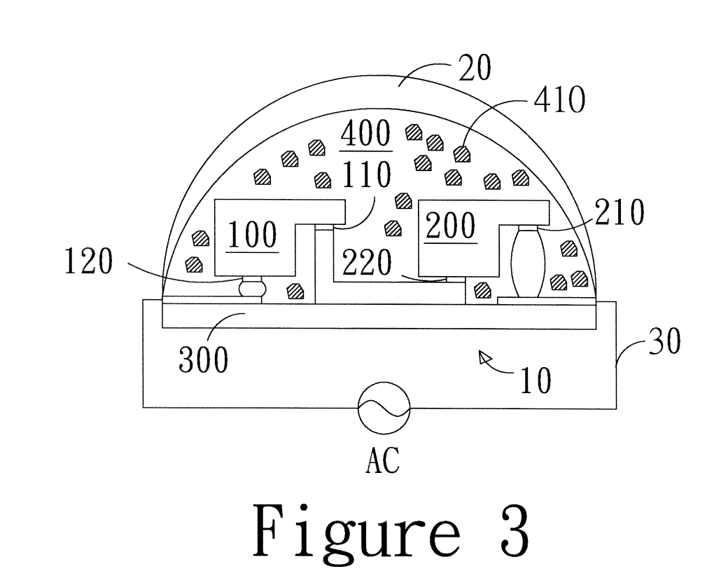

FIG. 3 shows a structural schematic diagram according to another preferred embodiment of the present invention. As shown in the figure, the structure and light compensation layer according an embodiment of a practical AC LED 10 are used for description. The AC LED 10 comprises a first lateral LED chip 100 and a second lateral LED chip 200. The first lateral LED chip 100 comprises a first electrode 110 and a second electrode 120; the second lateral LED chip 200 comprises a third electrode 210 and a fourth electrode 220. The first and second lateral LED chips 100, 200 are reversely disposed on a substrate 300. The second and fourth electrodes 120, 220 are disposed on the substrate 300, respectively. The first electrode 110 is connected electrically with the fourth electrode 220; the second electrode 120 and the third electrode 210 are connected to an AC power supply 30. If a package layer 400 of the AC LED 10 contains light conversion materials 410, the light compensation layer 20 is disposed on or under (not shown in the figure) the package layer 400, so long as the side being the light-emitting surface of the AC LED 10. On the contrary, if the package layer 400 of the AC LED 10 contains no light conversion materials 410, the package layer 400 can be combined with the light compensation layer 20 (not shown in the figure).

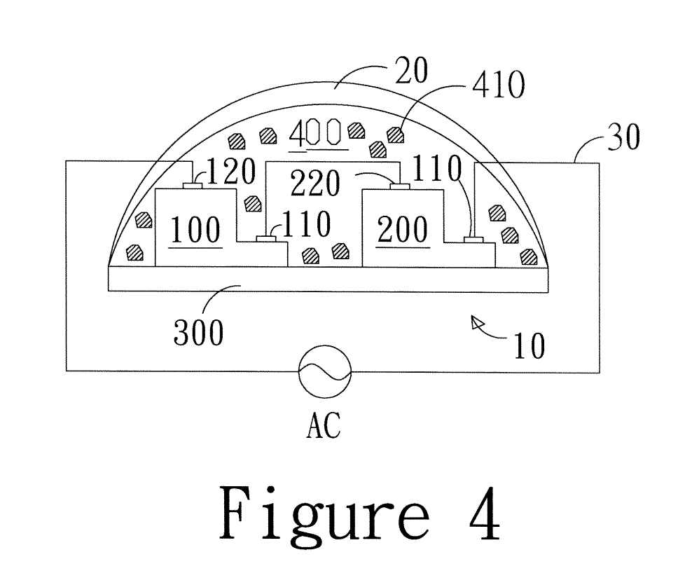

FIG. 4 shows a structural schematic diagram according to another preferred embodiment of the present invention. As shown in the figure, the structure and light compensation layer according an embodiment of a practical AC LED 10 are used for description. The AC LED 10 comprises a first lateral LED chip 100 and a second lateral LED chip 200. The first lateral LED chip 100 comprises a first electrode 110 and a second electrode 120; the second lateral LED chip 200 comprises a third electrode 210 and a fourth electrode 220. The first and second lateral LED chips 100, 200 are disposed on a substrate 300. The first electrode 110 is connected electrically with the fourth electrode 220; the second electrode 120 and the third electrode 210 are connected to an AC power supply 30. If a package layer 400 of the AC LED 10 contains light conversion materials 410, the light compensation layer 20 is disposed on or under (not shown in the figure) the package layer 400, so long as the side being the light-emitting surface of the AC LED 10. On the contrary, if the package layer 400 of the AC LED 10 contains no light conversion materials 410, the package layer 400 can be combined with the light compensation layer 20 (not shown in the figure).

If an ultraviolet (UV) LED chip is used, the light compensation layer 20 according to the present invention can be chosen from the group consisting of red phosphorescent powders, green phosphorescent powders, blue phosphorescent powders, red fluorescent powders, green fluorescent powders, blue fluorescent powders, and any combination of the above. According to design purpose, the light compensation layer 20 can emit white light during light emitting of the UV LED.

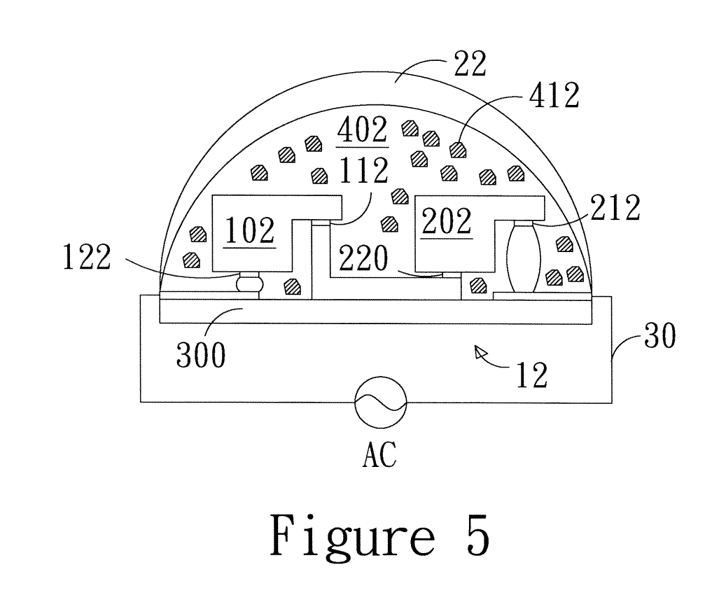

FIG. 5 shows a structural schematic diagram according to another preferred embodiment of the present invention. As shown in the figure, the structure and light compensation layer according an embodiment of a practical AC LED 12 are used for description. The AC LED 12 comprises a first lateral LED chip 102 and a second lateral LED chip 202. The first lateral LED chip 102 comprises a first electrode 112 and a second electrode 122; the second lateral LED chip 202 comprises a third electrode 212 and a fourth electrode 222. The first and second lateral LED chips 102, 202 are reversely disposed on a substrate 300. The second and fourth electrodes 122, 222 are disposed on the substrate 300, respectively. The first electrode 112 is connected electrically with the fourth electrode 222; the second electrode 122 and the third electrode 212 are connected to an AC power supply 30. In addition, the first and second lateral LED chips 102, 202 are UV LED chips. If a package layer 402 of the AC LED 12 contains light conversion materials 412, the light compensation layer 20 is disposed on or under (not shown in the figure) the package layer 402, so long as the side being the light-emitting surface of the AC LED 12. On the contrary, if the package layer 402 of the AC LED 12 contains no light conversion materials 412, the package layer 402 can be combined with the light compensation layer 20 (not shown in the figure).

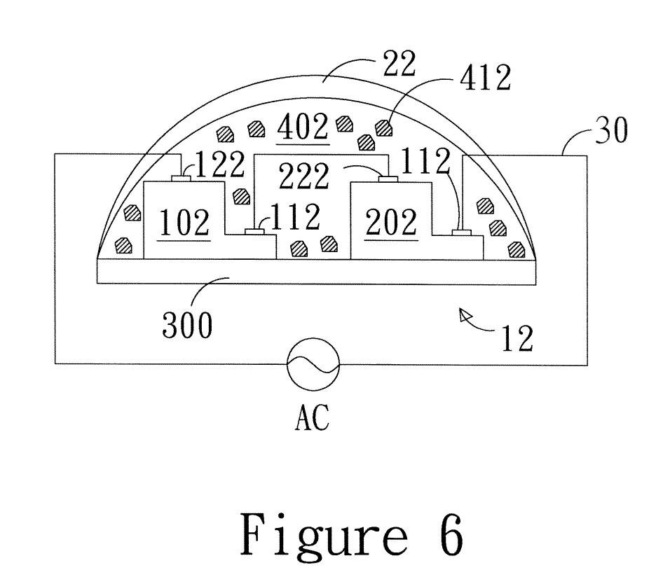

FIG. 6 shows a structural schematic diagram according to another preferred embodiment of the present invention. As shown in the figure, the structure and light compensation layer according an embodiment of a practical AC LED 12 are used for description. The AC LED 12 comprises a first lateral LED chip 102 and a second lateral LED chip 202. The first lateral LED chip 102 comprises a first electrode 112 and a second electrode 122; the second lateral LED chip 202 comprises a third electrode 212 and a fourth electrode 222. The first and second lateral LED chips 102, 202 are disposed on a substrate 300. The first electrode 112 is connected electrically with the fourth electrode 222; the second electrode 122 and the third electrode 212 are connected to an AC power supply 30. In addition, the first and second lateral LED chips 102, 202 are UV LED chips. If a package layer 402 of the AC LED 12 contains light conversion materials 412, the light compensation layer 20 is disposed on or under (not shown in the figure) the package layer 402, so long as the side being the light-emitting surface of the AC LED 12. On the contrary, if the package layer 402 of the AC LED 12 contains no light conversion materials 412, the package layer 402 can be combined with the light compensation layer 20 (not shown in the figure).

Besides, the relative positions of the light conversion materials and light compensation layers in FIGS. 3 to 6 can be interchanged arbitrarily or be combined to a single layer. This is well known to a person having ordinary skill in the art, and will not be described in more details.

Accordingly, the present invention conforms to the legal requirements owing to its novelty, nonobviousness, and utility. However, the foregoing description is only embodiments of the present invention, not used to limit the scope and range of the present invention. Those equivalent changes or modifications made according to the shape, structure, feature, or spirit described in the claims of the present invention are included in the appended claims of the present invention.

1. An alternating current light-emitting device, comprising:
an alternating current light-emitting diode; and
a light compensation layer, disposed on the light-emitting surface of said alternating current light-emitting diode;
where in each cycle of power, the light-emitting duration of said alternating current light-emitting diode is shorter than the light-emitting duration of said light compensation layer.

2. The alternating current light-emitting device of claim 1, wherein the material of said light compensation layer is chosen from the group consisting of yellow fluorescent powders, green fluorescent powders, red fluorescent powders, and any combination of the above.

3. The alternating current light-emitting device of claim 1, wherein the material of said light compensation layer is chosen from the group consisting of yellow phosphorescent powders, green phosphorescent powders, red phosphorescent powders, and any combination of the above.

4. The alternating current light-emitting device of claim 1, wherein said alternating current light-emitting diode includes a blue light-emitting diode chip.

5. The alternating current light-emitting device of claim 4, wherein the material of said light compensation layer is chosen from the group consisting of yellow fluorescent powders, yellow phosphorescent powders, red fluorescent powders, red phosphorescent powders, and any combination of the above.

6. The alternating current light-emitting device of claim 1, wherein said alternating current light-emitting diode includes an ultraviolet light-emitting diode chip.

7. The alternating current light-emitting device of claim 6, wherein the material of said light compensation layer is chosen from the group consisting of red fluorescent powders, green fluorescent powders, blue fluorescent powders, red phosphorescent powders, green phosphorescent powders, blue phosphorescent powders, and any combination of the above.

8. The alternating current light-emitting device of claim 1, wherein the material of said light compensation layer is chosen from the group consisting of ZnS, CaS, SrAl₂O₄, CaAl₂O₄, CaSrS, Sr₄Al₁₄O₂₅, and coordination compounds containing Pd.

9. The alternating current light-emitting device of claim 1, wherein the light-emitting mechanism of said light compensation layer is mainly the light-emitting mechanism of electron-hole pairs in a triplet state.

10. The alternating current light-emitting device of claim 1, wherein said alternating current light-emitting diode comprises:
a first lateral light-emitting diode chip, including a first electrode and a second electrode; and
a second lateral light-emitting diode chip, including a third electrode and a fourth electrode;
where said first and second lateral LED chips are reversely disposed on a substrate; said second and fourth electrodes are disposed on said substrate, respectively; said first electrode is connected electrically with said fourth electrode; and said second electrode and said third electrode are connected to an alternating current power supply.

11. The alternating current light-emitting device of claim 1, wherein said alternating current light-emitting diode comprises:
a first lateral light-emitting diode chip, including a first electrode and a second electrode; and
a second lateral light-erm diode chip, including a third electrode and a fourth electrode;
where said first and second lateral LED chips are disposed on a substrate; said first electrode is connected electrically with said fourth electrode; and said second electrode and said third electrode are connected to an alternating current power supply.

12. The alternating current light-emitting device of claim 1, wherein said alternating current light-emitting diode includes a package layer, containing a light conversion material, disposed between said light-emitting diode and said light compensation layer or on said light compensation layer, or disposed by combining with said light compensation layer.
